(19) United States
(12) Patent Application Publication
(10) Pub. No.: US 2006/0163621 A1
(43) Pub. Date: Jul. 27, 2006

(54) Pre-insulating substrate, method of manufacturing substrate, method of manufacturing surface acoustic wave resonator, surface acoustic wave resonator, surface acoustic wave device, and electronic apparatus

(75) Inventor: Hironori Hasei, Okaya (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/314,646

(22) Filed: Dec. 21, 2005

(30) Foreign Application Priority Data
Jan. 26, 2005 (JP) 2005-017923

(51) Int. Cl. H01L 27/20

(52) U.S. Cl. 257/254

(57) ABSTRACT

A pre-insulating substrate includes a base including an electrically conductive portion on a surface of the base, and a protective film disposed on the surface of the base to cover part of the conductive portion so as to prevent insulating treatment from being implemented for the part of the conductive portion. The protective film has a peripheral part that is thicker than a region other than the peripheral part in the protective film.

### BACKGROUND

1. Technical Field

The present invention relates to a pre-insulating substrate having a protective film for preventing insulating treatment from being implemented for part of an electrically conductive portion on the surface of the substrate, a method of manufacturing a substrate in which insulating treatment is implemented for the pre-insulating substrate, a method of manufacturing a surface acoustic wave resonator, a surface acoustic wave resonator manufactured with this manufacturing method, a surface acoustic wave device, and an electronic apparatus.

2. Related Art

A surface acoustic wave resonator used to electrically drive or sense a surface acoustic wave (sometimes abbreviated as SAW hereinafter) is manufactured by forming interdigital transducers (abbreviated as IDT hereinafter), reflectors and conductive pads on the surface of a piezoelectric substance such as a quartz piece with using a thin film composed of aluminum or the like. In such a surface acoustic wave resonator, if a conductive foreign matter adheres to the surface of the IDT, there arise problems that the frequency varies, and that stable resonating characteristics are not obtained, etc. Therefore, it is desirable that the surfaces of the IDTs are covered with an insulating substance. In contrast, since the conductive pads are portions to be coupled to external wires, it is desirable that the surface thereof keeps conductivity without being covered by an insulating substance.

As a technique for manufacturing a surface acoustic wave resonator that satisfies such requirements, a technique disclosed in JP-A-11-330882 as an example of the related art is known. This technique encompasses a protective film forming technique utilizing photolithography. Specifically, resist is initially applied on the entire surface of a piezoelectric substance on which IDTs, reflectors and conductive pads that are made of an aluminum thin film have been formed. The resist is then developed so that a resist film as a protective film against anodization to be described later is left only on the conductive pads. Subsequently, the entire surface of the aluminum thin film is anodized to thereby form an oxide film, and then the resist film on the conductive pads is removed. According to this technique, the surfaces of the IDTs and reflectors are covered with an oxide film, which is an insulating substance. In contrast, since the surfaces of the conductive pads are protected by the resist film, the oxide film is not formed thereon even through the anodization, resulting in a state in which the aluminum thin film is exposed.

Furthermore, in recent years, a method has been proposed in which resist as a protective film is selectively provided only on conductive pads by using an ink jet method. This method can reduce the amount of resist to be used. In addition, a process of developing resist can be omitted, which eliminates the need for a photo mask and thus can suppress manufacturing costs. Moreover, the method can avoid a problem that the surface of the aluminum thin film is deteriorated by the resist developer.

However, applying resist by an ink jet method involves a tendency of insufficient thickness of the resultant resist film. If the thickness of peripheral part of the resist film is insufficient in particular, there arises a problem that, through the anodization process, an oxide film is also partly formed on the region covered with the resist film as the protective film. This is because an insufficient thickness of peripheral part of the resist film permits the anodizing liquid to penetrate the interface between the conductive pads and the resist film from the outer periphery of the resist film. Although this problem can be avoided by repeating the application of resist by an ink jet method until the resist film has a sufficient thickness, the repetition of the resist application causes another problem of productivity lowering.

### SUMMARY

One advantage of some aspects of the invention is to provide a pre-insulating substrate including a protective film that has sufficient robustness against insulating treatment and offers high productivity. Another advantage of some aspects of the invention is to provide a method of manufacturing a substrate and a method of manufacturing a surface acoustic wave resonator that both allow insulating treatment only for desired regions of conductive portions on the surface of the substrate. A further advantage of some aspects of the invention is to provide a surface acoustic wave resonator, a surface acoustic wave device and an electronic apparatus that each have high reliability.

A pre-insulating substrate according to a first aspect of the invention includes a base having an electrically conductive portion on the surface of the base, and a protective film disposed on the surface of the base to cover part of the conductive portion so as to prevent insulating treatment from being implemented for the part of the conductive portion. The protective film has a peripheral part that is thicker than a region other than the peripheral part in the protective film. In addition, it is preferable that the thickness of the peripheral part of the protective film is at least twice the thickness of the region other than the peripheral part and is at most ten times the thickness of the region.

One of advantages achieved by the above-described configuration is that the protective film has sufficient robustness (adhesive strength) against the insulating treatment implemented for the substrate surface.

Furthermore, the material of the protective film included in the pre-insulating substrate may be resist.

One of advantages achieved by this configuration is that the protective film can be removed easily by using a certain method.

A second aspect of the invention is to provide a method of manufacturing a substrate by implementing insulating treatment for a region other than part of an electrically conductive portion on a surface of a base. The method includes heating the base that includes the conductive part on the surface of the base, applying a functional liquid on the base by using a droplet discharge device so as to cover the part of the conductive portion, and drying the functional liquid to form a pre-insulating substrate including a protective film on a surface of the pre-insulating substrate. The protective film has a peripheral part that is thicker than a region other than the peripheral part in the protective film. The method further includes implementing insulating treatment for the surface of the pre-insulating substrate, and removing the protective film. By heating the substrate in the heating process, the functional liquid can be dried so that the peripheral part becomes thicker. The protective film thus formed with the thick peripheral part has an advantage of being provided with a high adhesive strength to the base. Therefore, in the method of manufacturing a substrate according to the second aspect, there is little possibility that, in the insulating treatment, a liquid for the insulating treatment penetrates the interface between the protective film and the base.

A third aspect of the invention is to provide a method of manufacturing a substrate by implementing insulating treatment for a region other than part of an electrically conductive portion on a surface of a base. The method includes applying a functional liquid on the base that includes the conductive portion on the surface of the base by using a droplet discharge device so as to cover the part of the conductive portion. A solvent of the functional liquid has a boiling point in the range from 170° C. to 250° C. The method also includes drying the functional liquid to form a pre-insulating substrate including a protective film on a surface of the pre-insulating substrate. The protective film has a peripheral part that is thicker than a region other than the peripheral part in the protective film. The method further includes implementing insulating treatment for the surface of the pre-insulating substrate, and removing the protective film. In addition, the method may further include heating the substrate prior to the applying a functional liquid. The functional liquid of which solvent has a boiling point in the range of 170° C. to 250° C. results in a thicker peripheral part when dried. The protective film thus formed with the thick peripheral part has an advantage of being provided with a high adhesive strength to the base. Therefore, also in the method of manufacturing a substrate according to the third aspect, there is little possibility that, in the insulating treatment, a liquid for the insulating treatment penetrates the interface between the protective film and the base.

Furthermore, the insulating treatment may include treatment with anodization.

In addition, it is preferable that the thickness of the peripheral part of the protective film is at least twice the thickness of the region other than the peripheral part and is at most ten times the thickness of the region.

One of advantages achieved by the above-described method is that a substrate can easily be obtained in which insulating treatment is implemented only for desired regions of the substrate surface by using the protective film offering high productivity and having sufficient robustness (adhesive strength) against the insulating treatment for the substrate surface.

In the heating the base in the above-described method of manufacturing a substrate, it is preferable that the base is heated to a temperature in the range from 30° C. to 120° C. More preferably, the base is heated to a temperature in the range from 40° C. to 60° C. If the heating temperature of the base is 30° C. or higher, the thickness of peripheral part of the protective film becomes at least twice the thickness of the region other than the peripheral part. Furthermore, if the heating temperature of the base is 120° C, or lower, the thickness of peripheral part of the protective film becomes at most ten times the thickness of the region other than the peripheral part.

One of advantages achieved by the above-described method is that the protective film has sufficient robustness (adhesive strength) against the insulating treatment implemented for the substrate surface.

Moreover, the functional liquid used in the above-described method of manufacturing a substrate may include resist.

One of advantages achieved by this method is that the protective film can be removed easily by using a certain method.

The aspects of the invention can be carried out with various embodiments thereof For example, the aspects of the invention can be carried out as a method of manufacturing a surface acoustic wave resonator. In addition, to the surface acoustic wave resonator manufactured by this method of manufacturing a surface acoustic wave resonator, external wires can be coupled easily and surely through, of the conductive portions on the base surface, the portion that has been protected by the protective film against the insulating treatment. Moreover, troubles do not arise even when a conductive foreign matter or the like adheres to the insulated portions of the conductive portions on the base surface. Thus, the surface acoustic wave resonator manufactured by the above-described method of manufacturing a surface acoustic wave resonator has high reliability. In addition, a surface acoustic wave device and an electronic apparatus including the surface acoustic wave resonator can achieve high reliability.

### BRIEF DESCRIPTION OF THE DRAWINGS

The invention will be described with reference to the accompanying drawings, wherein like numbers refer to like elements.

FIG. 1 is a schematic diagram illustrating a manufacturing apparatus for a substrate.

FIG. 2 is a schematic perspective view illustrating a droplet discharge device.

FIGS. 3A and 3B are a schematic perspective view and a side sectional view, respectively, of part of a head in the droplet discharge device.

FIG. 4 is a functional block diagram of a controller in the droplet discharge device.

FIG. 5 is a schematic plan view of a base having SAW patterns.

FIGS. 6A and 6B are enlarged perspective views of the base.

FIG. 6C is a schematic perspective view of a surface acoustic wave resonator.

FIGS. 7A and 7B are enlarged views of a conductive pad on which a protective film has been formed.

FIGS. 8A to 8E are schematic side views illustrating a method of manufacturing a substrate according to an embodiment of the invention.

FIGS. 9A to 9C are schematic side views illustrating a process of formation of the protective film on the base.

FIG. 10 is a schematic diagram illustrating an anodizing device.

FIGS. 11A and 11B are a side sectional view and a plan view, respectively, illustrating an oscillator of an embodiment of the invention.

FIG. 12 is a schematic perspective view of a cellular phone of an embodiment of the invention.

### DESCRIPTION OF EXEMPLARY EMBODIMENTS

Embodiments of the invention will be described below with reference to the accompanying drawings.

Surface Acoustic Wave Resonator

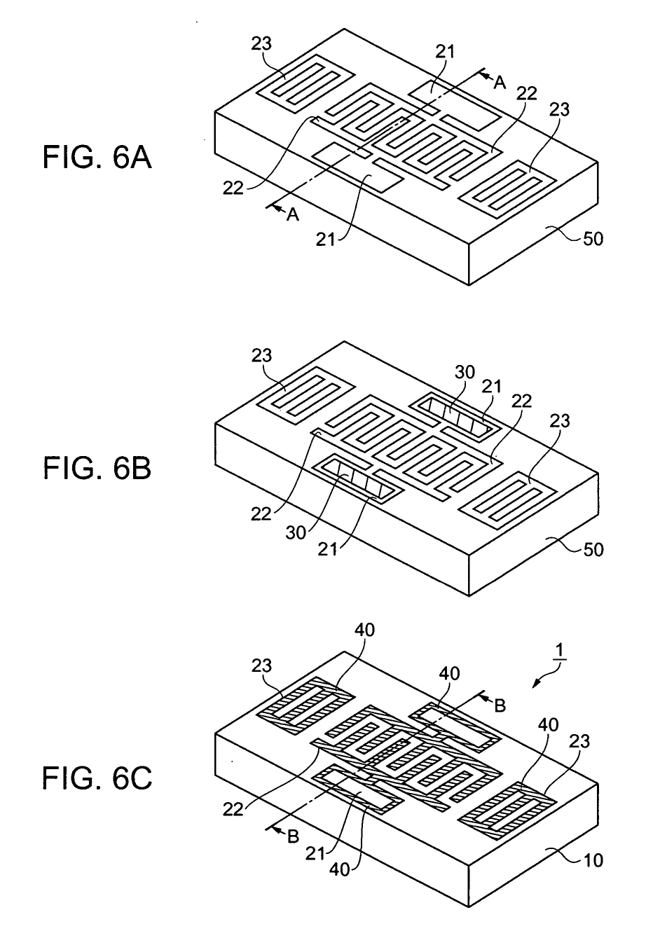

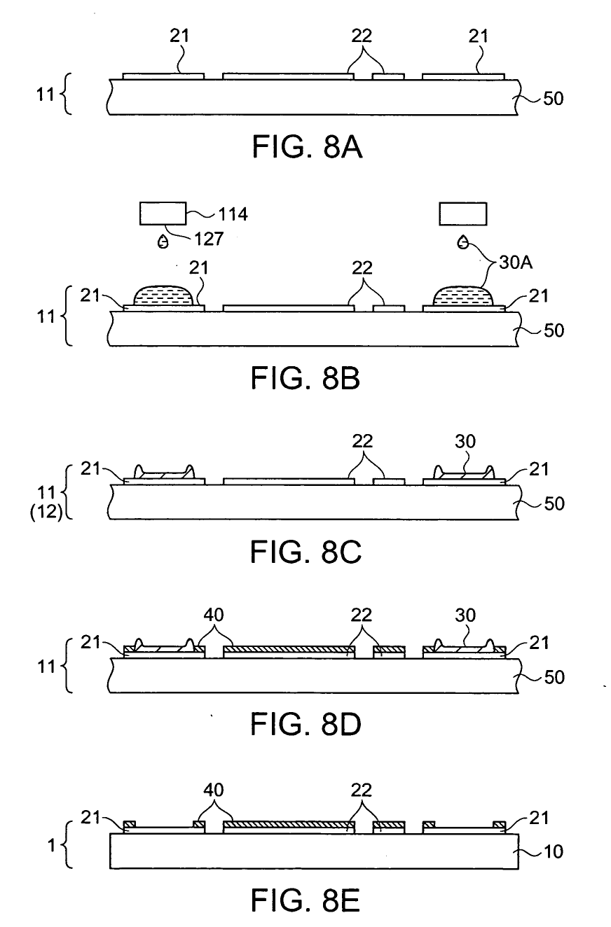

FIG. 6C is a schematic diagram of a surface acoustic wave resonator manufactured by using a method of manufacturing a substrate according to an embodiment of the invention. FIG. 8E is a sectional view obtained by cutting the surface acoustic wave resonator along line B-B of FIG. 6C. A surface acoustic wave resonator 1 includes a quartz piece 10, conductive pads 21 made of an aluminum thin film, IDTs 22, reflectors 23, and an insulating layer 40 made of an aluminum oxide film. The hatched areas in FIG. 6C indicate the regions on which the insulating layer 40 has been formed. Note that the conductive pads 21, the IDTs 22 and the reflectors 23 correspond to “an electrically conductive portion on the surface of a substrate” in the present invention.

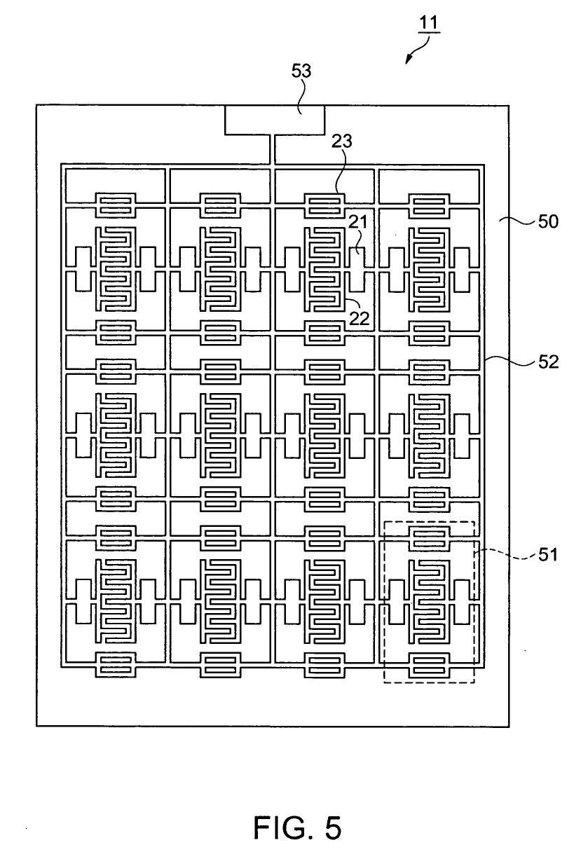

The quartz piece 10 is a piezoelectric substance obtained by cutting a quartz wafer 50 (refer to FIG. 5) into a rectangular parallelepiped. Disposed on the surface of the quartz piece 10 is a pair of IDTs 22 having such a shape that comb teeth thereof interdigitate with each other so as to be juxtaposed to each other. The IDTs 22 are coupled to the conductive pads 21 formed of an aluminum thin film monolithic with that of the IDTs 22. The conductive pads 21 are portions for coupling external wires (not shown) thereto. The order of size of the conductive pads 21 is typically such that one side thereof is about several hundreds micrometers in length. A pair of reflectors 23 is disposed to sandwich the IDTs 22. The reflectors 23 are formed by the same aluminum thin film forming process as that for the IDTs 22 and the conductive pads 21.

When a high frequency signal is applied from external wires via the conductive pads 21 to the IDTs 22, an electric field arises between the electrodes and thus a surface acoustic wave is excited so as to be propagated on the quartz piece 10. The surface acoustic wave is repeatedly reflected by the reflectors 23, and thus a standing wave of the surface acoustic wave is established on the quartz piece 10. Thus, the surface acoustic wave resonator 1 functions as a resonator that confines surface acoustic wave energy by utilizing the reflection of the surface acoustic wave.

In the surface acoustic wave resonator 1 having the above-described structure, if a foreign matter adheres to the surface of the IDT 22 or the reflector 23, there arises problems that the frequency varies, and that stable resonating characteristics are not obtained, etc. In addition, if short-circuit arises between the pair of IDTs 22 due to a conductive foreign matter, the function itself as a surface acoustic wave resonator is spoiled. In order to avoid these troubles, the surfaces of the IDTs 22 and the reflectors 23 and part of the surfaces of the conductive pads 21 are covered with the insulating layer 40 formed by oxidizing the surface of the aluminum thin film. Covering the surfaces of the IDTs 22 and the reflectors 23 with the insulating layer 40 prevents the occurrence of the above-described troubles even when a conductive foreign matter or the like adheres to the region in which the IDTs 22 or the reflectors 23 are disposed.

Manufacturing Apparatus

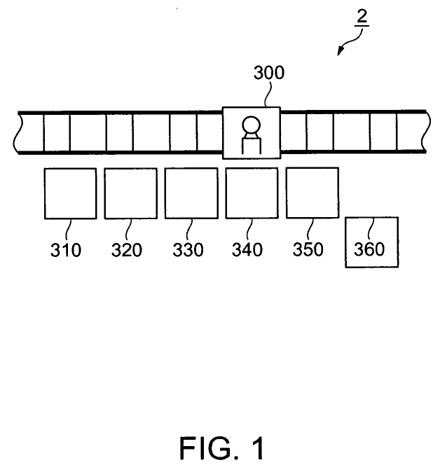

A manufacturing apparatus 2 used for manufacturing the surface acoustic wave resonator 1 will be described with reference to FIG. 1. Hereinafter, the quartz wafer 50 (refer to FIG. 5) having on the surface thereof the conductive pads 21, the IDTs 22, the reflectors 23, a coupling line 52 and a terminal 53 that all are composed of an aluminum thin film, is expressed as a base 11. The base 11 has twelve SAW patterns 51 on the surface of the quartz wafer 50. Each of the SAW patterns 51 includes the conductive pads 21, the IDTs 22 and the reflectors 23, and one SAW pattern corresponds to one surface acoustic wave resonator 1. Although the number of the SAW patterns 51 is twelve for convenience of explanation in the present embodiment, an actual base 11 typically has a larger number of the SAW patterns 51 depending on the size of the quartz wafer 50 and the size of the surface acoustic wave resonator 1 to be manufactured.

The manufacturing apparatus 2 shown in FIG. 1 is an apparatus for forming the insulating layer 40 on certain regions on the surface of the base 11 so as to manufacture a substrate including a plurality of surface acoustic wave resonators 1. The manufacturing apparatus 2 includes a cleaning device 310 for cleaning the surface of the base 11, a heating device 320 for heating the base 11, and a droplet discharge device 330 for applying a protective material 30A (refer to FIG. 8B) that is a liquid material on certain regions on the surface of the base 11. The manufacturing apparatus 2 further includes a drying device 340, an anodizing device 350 and a removal device 360. The drying device 340 dries the protective material 30A on the surface of the base 11 to thereby form a protective film 30. The anodizing device 350 anodizes the surfaces of the conductive pads 21 and the IDTs 22 to thereby form the insulating layer 40 on, of the surfaces of the conductive pads 21 and the IDTs 22, the regions on which the protective film 30 is not formed. The removal device 360 removes the protective film 30 from the base 11.

Furthermore, the manufacturing apparatus 2 also includes a carrying device 300 for carrying the base 11 though the cleaning device 310, the heating device 320, the droplet discharge device 330, the drying device 340, the anodizing device 350, and the removal device 360 in that order.

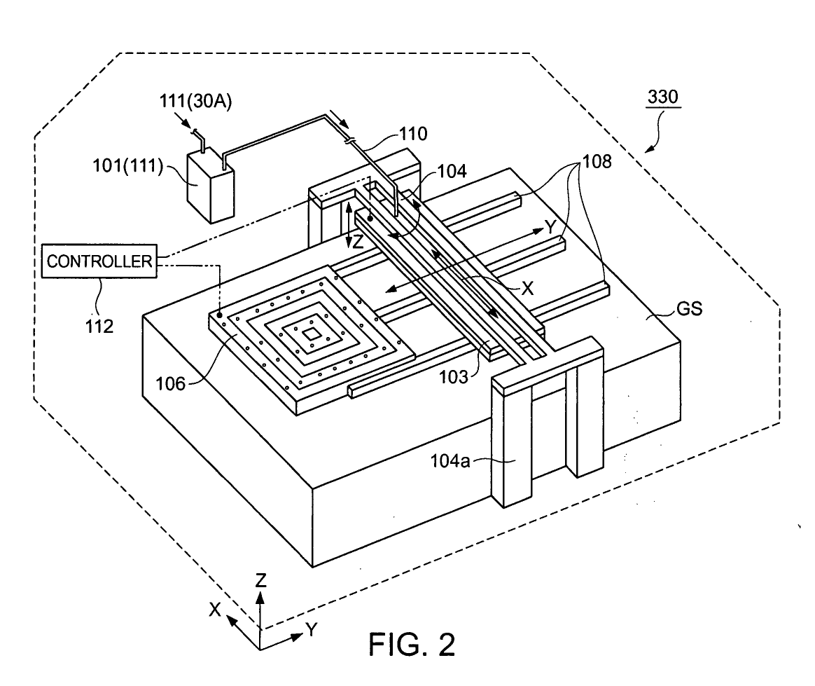

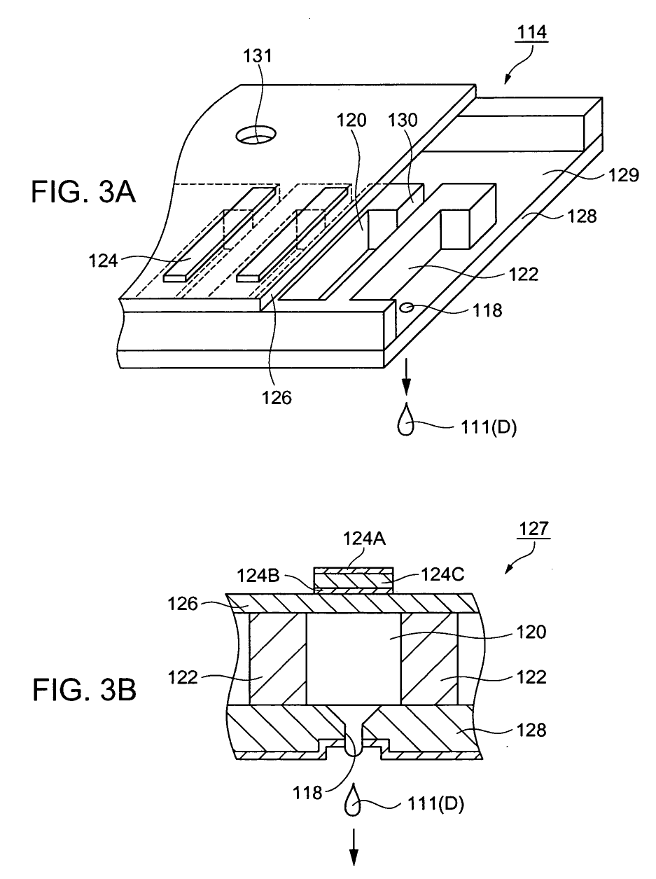

Note that the protective material 30A corresponds to “functional liquid” in the present invention. The protective material 30A is a type of a liquid material 111 (refer to FIGS. 2, 3A and 3B) to be described later.

Entire Structure of Droplet Discharge Device

The entire structure of the droplet discharge device 330 will be described below with reference to FIG. 2. The droplet discharge device 330 in FIG. 2 is basically an ink jet device for discharging the liquid material 111 (protective material 30A). More specifically, the droplet discharge device 330 includes a tank 101 storing the liquid material 111, a tube 110, a ground stage GS, a discharge head unit 103, a stage 106, a first position control unit 104, a second position control unit 108, a controller 112, and supports 104a.

The discharge head unit 103 holds a head 114 (refer to FIG. 3). The head 114 discharges droplets of the liquid material 111 based on a signal from the controller 112. The head 114 held by the discharge head unit 103 is coupled to the tank 101 by the tube 110. Accordingly, the liquid material 111 is supplied from the tank 101 to the head 114.

The stage 106 provides a flat surface for fixing the base 11 thereon. The stage 106 also has a function of surely fixing the position of the base 11 by suction.

The first position control unit 104 is fixed by the supports 104a at a certain height from the ground stage GS. The first position control unit 104 has a function of moving the discharge head unit 103 in the X-axis direction and the Z-axis direction, which is perpendicular to the X-axis direction, based on a signal from the controller 112. In addition, the first position control unit 104 also has a function of rotating the discharge head unit 103 about an axis parallel to the Z-axis. In the present embodiment, the Z-axis direction refers to the direction parallel to the vertical direction (i.e., the direction of gravitational acceleration).

The second position control unit 108 moves the stage 106 on the ground stage GS in the Y-axis direction based on a signal from the controller 112. The Y-axis direction is perpendicular to both the X-axis and Z-axis directions.

The first and second position control units 104 and 108 with the above-described functions can be achieved by using a known XY robot employing a linear motor or servomotor. Detailed description of the structure thereof is therefore omitted.

As described above, the first position control unit 104 moves the discharge head unit 103 in the X-axis direction. In addition, the second position control unit 108 moves the base 11 together with the stage 106 in the Y-axis direction. As a result, the relative position of the head 114 to the base 11 changes. More specifically, these movements allow the discharge head unit 103, the head 114, and nozzles 118 (refer to FIG. 3) to move in the X-axis and Y-axis directions relative to the base 11 fixed on the stage 106, i.e., to relatively scan the base 11, with keeping a certain distance from the base 11 to the head 14 in the Z-axis direction. The relative movement or relative scanning refers to moving at least one of a discharger of the liquid material 111 and a substance on which the discharged matter is to land (discharged-matter receiver, hereinafter) relative to the other.

The controller 112 receives, from an external information processor, discharge data indicating relative positions on which the liquid material 111 should be discharged. The controller 112 stores the received discharge data in its internal memory, and controls the first position control unit 104, the second position control unit 108, and the head 114 based on the stored discharge data. Note that the discharge data is data for applying the liquid material 111 on the base 11 into a certain pattern. In the present embodiment, the discharge data has a form of bitmap data.

The droplet discharge device 330 having the above-described structure moves the nozzles 118 (refer to FIG. 3) of the head 114 relative to the base 11 and discharges the liquid material 111 from the nozzles 118 to the discharged-matter receiver, according to the discharge data.

Note that forming a layer, film or pattern with an ink jet method refers to forming a layer, film or pattern on a certain substance by using an apparatus such as the droplet discharge device 330.

Head.

As shown in FIGS. 3A and 3B, the head 114 included in the droplet discharge device 330 is an ink jet head having a plurality of nozzles 118. More specifically, the head 114 includes a diaphragm 126 and a nozzle plate 128 that defines the opening of each nozzle 118. Provided between the diaphragm 126 and the nozzle plate 128 is a reservoir 129. The reservoir 129 is always filled with the liquid material 111 supplied from an external tank (not shown) through a hole 131.

A plurality of partition walls 122 are disposed between the diaphragm 126 and the nozzle plate 128. The area surrounded by the diaphragm 126, the nozzle plate 128 and a pair of partition walls 122 corresponds to a cavity 120. Each cavity 120 is provided for a corresponding one of the nozzles 118, and therefore the number of the cavities 120 is equal to that of the nozzles 118. The liquid material 111 is supplied from the reservoir 129 to each of the cavities 120 through a supply opening 130 placed between a pair of partition walls 122. The diameter of each nozzle 118 is approximately 27 μm in the present embodiment.

On the diaphragm 126, each of resonators 124 is provided corresponding to a respective one of the cavities 120. Each of the resonators 124 includes a piezo element 124C, and a pair of electrodes 124A and 124B that sandwich the piezo element 124C. The controller 112 provides a driving voltage across the pair of electrodes 124A and 124B, which discharges a droplet D of the liquid material 111 from the corresponding nozzle 118. Here, the volume of the material discharged from the nozzle 118 is variable within the range of 0 to 42 picoliters. The shape of the nozzle 118 is adjusted so that the droplets D of the liquid material 111 are discharged from the nozzle 118 in the Z-axis direction.

In the present specification, a part that includes one nozzle 118, the cavity 120 corresponding to the nozzle 118 and the resonator 124 corresponding to the cavity 120 is sometimes expressed as a discharge unit 127. According to this expression, one head 114 has the same number of the discharge units 127 as that of the nozzles 118. The discharge unit 127 may have an electrothermal converting element instead of a piezo element. That is, the discharge unit 127 may have a structure for discharging the material by use of thermal expansion of the material due to the electrothermal converting element.

Controller

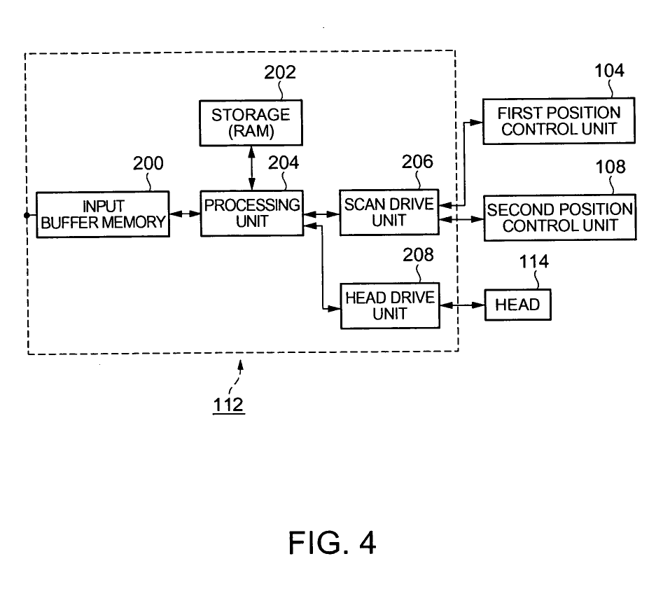

The configuration of the controller 112 will be described below. As shown in FIG. 4, the control unit 112 has an input buffer memory 200, a storage 202, a processing unit 204, a scan drive unit 206 and a head drive unit 208. The input buffer memory 200 and the processing unit 204 are coupled to each other so that they can communicate with each other. The processing unit 204, the storage 202, the scan drive unit 206 and the head drive unit 208 are coupled to each other via a bus (not shown) so as to be capable of communicating with each other.

The scan drive unit 206 is coupled to the first and second position control units 104 and 108 so as to be capable of mutually communicating with them. Similarly, the head drive unit 208 is coupled to the head 114, so that they can communicate with each other.

The input buffer memory 200 receives discharge data for discharging the liquid material 111 from an external information processing device (not shown) located outside the droplet discharge device 330. The input buffer memory 200 supplies the discharge data to the processing unit 204. The processing unit 204 then stores the discharge data in the storage 202. In FIG. 4, the storage 202 is a random access memory (RAM).

The processing unit 204 provides the scan drive unit 206 with data indicating the position of the nozzle 118 relative to the discharged-matter receiver base on the discharge data in the storage 202. The scan drive unit 206 provides the second position control unit 104 with a stage drive signal based on the discharge data and the discharge cycle. As a result, the relative position of the discharge head unit 103 to the discharged-matter receiver changes. The processing unit 204 provides, base on the discharge data stored in the storage 202, the head 114 with a discharge signal required for discharging the liquid material 111. Consequently, the corresponding nozzle 118 in the head 114 discharges the droplets D of the liquid material 111.

The controller 112 is a computer including a central processing unit (CPU), a read only memory (ROM), a RAM and a bus. Therefore, the above-described functions of the controller 112 are implemented with a software program executed by the computer. It should be obvious that the controller 112 may be achieved with a dedicated circuit (hardware).

Liquid Material

The liquid material 111 refers to a material having such viscosity that the material can be discharged as the droplets D from the nozzle 118 of the head 114. The liquid material 111 can be either a water- or oil-based material. It is enough for the liquid material 111 to have such fluidity (viscosity) that the material can be discharged from the nozzle 118, and it can even contain a solid matter as long as it is fluidic as a whole. It is preferable that the viscosity of the liquid material 111 is at least 1 mPa·s and at most 50 mPa·s. A viscosity of 1 mPa·s or more prevents periphery of the nozzle 118 from being fouled by the liquid material 111 when discharging the droplets D of the liquid material 111. In contrast, a viscosity of 50 mPa·s or less provides a small frequency of clogging of the nozzles 118, which allows smooth discharging of the droplets D. The liquid material 111 is also referred to as a functional liquid since it takes a specific function after being applied on the discharged-matter receiver.

The protective material 30A used in the present embodiment is the liquid material 111 satisfying the above-described requirements. The protective material 30A contains resist, and employs N-methyl-2-pyrrolidone as its solvent. When drying the protective material 30A discharged from the nozzle 118 of the head 114 to the discharged-matter receiver, the solvent evaporates. As a result, the protective film 30 composed of the resist is formed on the discharged-matter receiver. The protective film 30 can be removed by using a chemical for resist removal.

For the protective material 30A, various solvents can be used besides N-methyl-2-pyrrolidone used in the present embodiment. For example, besides water, the following materials can be exemplified: alcohols such as methanol, ethanol, propanol, and butanol; hydro-carbon compounds such as n-heptane, n-octane, decane, toluene, xylene, cymene, durene, indene, dipentene, tetrahydronaphthalene, decahydronaphthalene, and cyclohexylbenzene; ether compounds such as ethylene glycol dimethyl ether, ethylene glycol diethyl ether, ethylene glycol methyl ethyl ether, diethylene glycol dimethyl ether, diethylene glycol diethyl ether, diethylene glycol methyl ethyl ether, 1,2-dimethoxyethane, bis (2-methoxyethyl) ether, and p-dioxane; polar compounds such as propylene carbonate, gamma-butyrolactone, dimethylformamide, dimethyl sulfoxide, cyclohexanone, ethyl acetate, and butyl lactate; and so on.

Alternatively, the protective material 30A may employ a material that does not include a solvent, i.e., a non-solvent material. Specifically, any of the following thermoplastic or thermosetting resin can be used: acrylic resin typified by polymethyl methacrylate, polyhydroxyethyl methacrylate and polycyclohexyl methacrylate, allyl resin typified by polydiethyleneglycolbisaryl carbonate and polycarbonate, methacylate resin, polyurethane resin, polyester resin, polyvinylchloride resin, polyvinylacetate resin, cellulose resin, polyamide resin, fluororesin, polypropylene resin, and polystyrene resin. One kind or a mixture of plural kinds of these resins can be used.

Method of Manufacturing Substrate

A method of manufacturing the surface acoustic wave resonator 1 with using the manufacturing apparatus 2 that includes the droplet discharge device 330 will be described below with reference to FIGS. 1, and 5 to 9C.

Initially, by using a known film deposition technique and a patterning technique, formed on the quartz wafer 50 are the SAW pattern 51 including the conductive pads 21, the IDTs 22, the reflectors 23, the coupling line 52 and the terminal 53 that all are composed of an aluminum thin film, to thereby manufacture the base 11 (refer to FIG. 5). The conductive pads 21, the IDTs 22, the reflectors 23, the coupling line 52, and the terminal 53 can simultaneously be deposited through one aluminum thin film forming process. FIG. 6A is a diagram focusing on one of the plurality of SAW patterns 51 on the base 11. FIG. 8A is a sectional view obtained by cutting the base 11 along line A-A in FIG. 6A.

The base 11 on which the SAW patterns 51 have been formed is loaded in the manufacturing apparatus 2 of FIG. 1, followed by being carried to the cleaning device 310 by the carrying device 300. In the cleaning device 310, the surface of the base 11 is cleaned by ultrasonic cleaning in deionized water, UV-cleaning or the like.

The base 11 after the cleaning process is carried to the heating device 320 by the carrying device 300. The base 11 is heated to 50° C. in the heating device 320. Various methods are available to heat the base 11. Here, a method is used in which the chamber temperature of a thermostatic chamber capable of setting temperature is set to 50° C. and the base 11 is allowed to stand therein for a certain time period.

Subsequently, the base 11 is carried by the carrying device 300 to the stage 106 of the droplet discharge device 330. As shown in FIG. 8B, the droplet discharge device 330 then discharges the protective material 30A from the discharge unit 127 of the head 114 so that layers of the protective material 30A are formed on protection regions (i.e., regions to be protected) to be described later on the base 11. A time period from the heating of the base 11 by the heating device 320 to the discharging of the protective material 30A onto the base 11 is sufficiently short. Therefore, the temperature of the base 11 is kept at about 50° C. when the protective material 30A is discharged thereon.

After layers of the protective material 30A are formed on all protection regions on the base 11, the carrying device 300 locates the base 11 in the drying device 340. The drying device 340 then completely dries the protective material 30A on the base 11. This drying employs a method of allowing the base 11 to stand in an ambience of 120° C. for 30 minutes. Through this drying, the solvent in the protective material 30A evaporates, and thus the protective film 30 composed of the resist included in the protective material 30A is formed on the regions on which the protective material 30A has been discharged. Hereinafter, the base 11 having the protective film 30 on its surface is also referred to as a pre-insulating substrate 12.

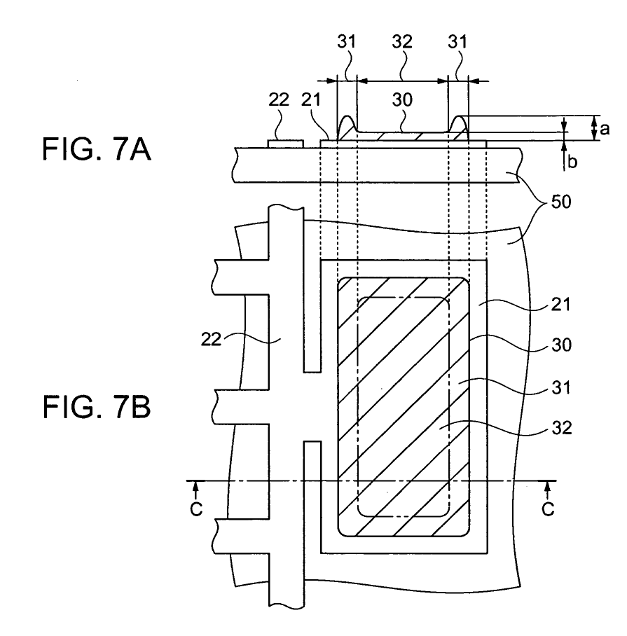

With reference to FIGS. 6B, 7A and 7B, description will be made about the region, on the base 11, on which the protective material 30A should be discharged by the droplet discharge device 330, i.e., the protection region, on which the protective film 30 should be formed. FIG. 6B is a diagram focusing on one SAW pattern on the base 11 on which the protective film 30 has been formed. The hatched areas in FIG. 6B indicate the regions on which the protective film 30 has been formed. FIG. 7B is a diagram magnifying the vicinity of the conductive pad 21 in FIG. 6B. FIG. 7A is a sectional view obtained by cutting the base 11 along line C-C in FIG. 7B. The protection region corresponds to the region on which the protective film 30 has been formed in FIGS. 6B, 7A and 7B. More specifically, the protection region is the region obtained by excluding the peripheral part of the conductive pad 21 from the entire surface of the conductive pad 21. This region is provided for coupling of an external wire as described above, and therefore it is preferable that the surface of this region keeps conductivity without the insulating layer 40 (FIG. 8E) being formed thereon through an anodization process to be described later. The region corresponds to “part of a conductive portion on the surface of a substrate” in the present invention.

Note that the protection region shown in FIGS. 6B, 7A and 7B is a region with the minimum area that should be ensured for achieving coupling of an external wire, and does not indicate the upper limit of area of the protection region. The protection region can be enlarged as long as it does not overlap with the region on which the insulating layer 40 should be formed. For example, the protection region may stretch beyond the outer circumference of the conductive pad 21 to the quartz wafer 50. However, in order to take full advantage of the method of forming the protective film 30 with using the droplet discharge device 330, which allows suppression of use amount of the protective material 30A, it is preferable that a region like that shown in FIGS. 6B, 7A and 7B is defined as the protection region.

In thus obtained protective film 30, as shown in FIG. 7A, the thickness of a peripheral part 31 is larger than that of the region other than the peripheral part 31, i.e., a center part 32 surrounded by the peripheral part 31. That is, the protective film 30 is composed of the flat center part 32 and the peripheral part 31 surrounding the center part 32 and being thicker than the center part 32. The protective film 30 in which the thickness of the peripheral part 31 is sufficiently large eliminates the possibility that an anodizing liquid penetrates the interface between the conductive pad 21 and the protective film 30 from the outer circumference of the protective film 30, and therefore such a protective film 30 has sufficient robustness (adhesive strength) against anodization. In addition, the protective film 30 can be formed by carrying out only once an applying step of the protective material 30A with the droplet discharge device 330. Therefore, the protective film 30 offers high productivity. Moreover, the pre-insulating substrate 12 having such a protective film 30 allows anodization for only desired regions of conductive portions on the substrate surface in the anodization process, as will be described later.

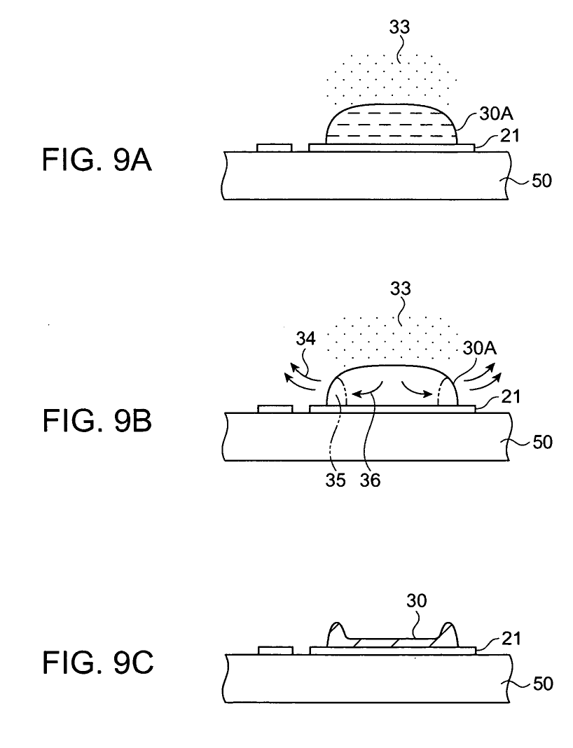

The reason why the peripheral part 31 of the protective film 30 becomes thicker than the center part 32 is probably as follows. FIG. 9A illustrates the protective material 30A that has been applied on the conductive pad 21 but has not been dried yet. A large amount of a gas 33 resulting from vaporization of the solvent of the protective material 30A exists above the protective material 30A. Therefore, around the protective material 30A, the vapor pressure of the solvent above the protective material 30A is higher than that near the side thereof. Accordingly, the solvent vaporizes mainly from the side of the protective material 30A as indicated with arrows 34 in FIG. 9B. Consequently, the solvent inside the protective material 30A moves toward regions 35 near the side surface of the protective material 30A (arrows 36) to compensate the solvent that has vaporized from the regions 35. In step with the movement of the solvent, the resist contained in the protective material 30A also simultaneously moves toward the regions 35 (arrows 36). The cycle composed of the vaporization of the solvent from the regions 35 near the side surface and the movement of the solvent and resist to the regions 35 is repeated until the protective material 30A has been dried. Thus, as shown in FIG. 9C, the protective material 30A is dried with the resist volume being biased to the peripheral part 31. As a result, the protective film 30 like that shown in FIGS. 7A and 7B in which the peripheral part 31 is thicker than the center part 32 is formed.

Here, the ratio a/b, which is the ratio of thickness a of the peripheral part 31 to the thickness b of the center part 32 shown in FIG. 7A, changes depending on the temperature of the base 11 and the boiling point of the solvent. When the temperature of the base 11 is high, the ratio a/b becomes large. This is probably because the protective material 30A applied on the high temperature base 11 has almost the same temperature as that of the base 11, which lowers the viscosity of the protective material 30A as liquid, and therefore the movement along the arrows 36 in the above-described cycle is repeated more rapidly until the drying of the protective material 30A. As a result, the bias of the resist volume toward the peripheral part 31 of the protective film 30 becomes large at the completion of the drying, resulting in a large ratio a/b. Furthermore, also when the boiling point of the solvent is high, the ratio a/b becomes large. This is because a high boiling point of the solvent leads to slow vaporization of the solvent from the protective material 30A, which extends a time period until the drying of the protective material 30A, during which the movement along the arrows 36 in the above-described cycle is repeated. As a result, the bias of the resist volume toward the peripheral part 31 of the protective film 30 becomes large at the completion of the drying, resulting in a large ratio a/b.

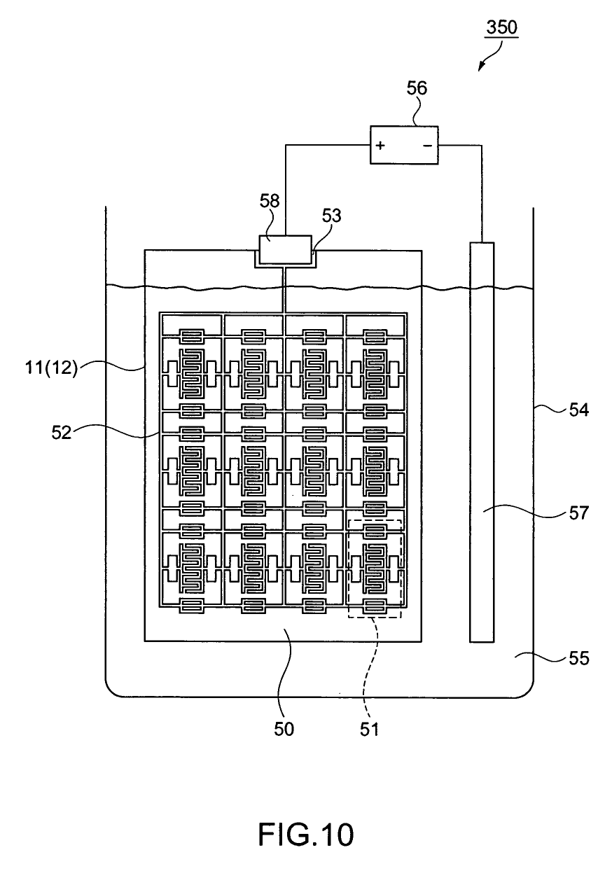

The base 11 in which the protective film 30 has been formed on the protection region (i.e., the pre-insulating substrate 12) is carried to the anodizing device 350 by the carrying device 300. FIG. 10 schematically illustrates the anodizing device 350. The anodizing device 350 includes a bath 54, an anodizing liquid 55, a power supply 56, a cathode 57, and a clip 58. The bath 54 contains the anodizing liquid 55. The cathode 57 coupled to the negative pole of the power supply 56 is immersed in the anodizing liquid 55. The positive pole of the power supply 56 is coupled to the clip 58. The clip 58 holds the terminal 53 on the base 11 immersed in the anodizing liquid 55. The terminal 53 on the base 11 is composed of an aluminum thin film monolithic with that of the coupling line 52, the conductive pads 21, the IDTs 22 and the reflectors 23. All the SAW patterns 51 on the base 11 are immersed in the anodizing liquid 55.

In the anodizing device 350 with such a configuration, a current is applied from the power supply 56 to thereby implement anodization, with the cathode 57 being a cathode and the base 11 being an anode. In the present embodiment, in order to form a non-porous oxide film on the surface of the aluminum thin film through the anodization, a mixture liquid of an aqueous solution of a phosphate or borate is used as the anodizing liquid 55. Besides these aqueous solutions, an aqueous solution of a salt with a pH near neutral such as a citrate or adipate can also be used. In addition, it is desirable that the liquid temperature is about a room temperature in order to avoid the formation of a porous oxide film. For example, it is desirable that the liquid temperature is between about 20° C. and 30° C. when an aqueous solution of a borate is used.

Through the anodization under such conditions, as shown in FIG. 8D, formed on the surfaces of the IDTs 22, the reflectors 23 and the conductive pads 21 is the insulating layer 40 composed of an aluminum oxide film with the thickness almost proportional to the applied voltage. However, of the surface of the conductive pads 21, the region on which the protective film 30 has been provided, i.e., the protection region is not provided with the insulating layer 40 since it is not in contact with the anodizing liquid 55. That is, the protective film 30 protects the surface of the conductive pads 21 against the anodization.

The adhesive strength of the protective film 30 against the anodization varies depending on the above-described ratio a/b. In order to provide the protective film 30 with sufficient adhesive strength against the anodization, it is desirable that the ratio a/b is in the range of 2 to 10. When the ratio a/b is smaller than 2, the thickness of peripheral part of the protective film is insufficient, and therefore there may be the case in which the anodizing liquid 55 penetrates the interface between the conductive pad and protective film from the outer circumference of the protective film. Accordingly, the insulating layer is formed on part of the protection region of the conductive pad. In contrast, if the ratio a/b is larger than 10, the absolute value of the thickness b of center part of the protective film is small and thus the strength of the center part is insufficient. Therefore, there is a possibility of removal of the center part in the anodization process. Accordingly, the insulating layer is formed on the region from which the protective film has been removed.

According to experiments by the inventors, there were cases in which the ratio a/b becomes smaller than 2 when the heating temperature of the base 11 is below 30° C. in the heating process for the base 11 with the above-described heating device 320. In addition, there were cases in which the ratio a/b becomes larger than 10 when the heating temperature of the base 11 is beyond 120° C. Therefore, it is preferable that the heating temperature of the base 11 with the heating device 320 is in the range of 30° C. to 120° C. Furthermore, it has been confirmed that the protective film 30 is provided with the highest robustness against the anodization when the heating temperature of the base 11 is in the range of 40° C. to 60° C. In the present embodiment, since the base 11 is heated to 50° C. in the heating process with the heating device 320, the protective film 30 has sufficient robustness against the anodization. Specifically, the situation is avoided in which the anodizing liquid 55 penetrates the interface between the protective film 30 and the conductive pad 21 and thus the insulating layer 40 is formed on part of the protection region. In addition, since there is no possibility of removal of the, center part 32 of the protective film 30, all the protection regions on the base 11 are surely protected against the anodization.

The base 11 in which the insulating layer 40 has been formed on the surfaces of the IDTs 22 and the reflectors 23 and part of the surfaces of the conductive pads 21 is carried to the removal device 360 by the carrying device 300. The removal device 360 removes the protective film 30 composed of resist and formed on the protection regions on the base 11 with using a certain chemical. Thus, in the protection regions on the conductive pads, aluminum, which has conductivity, is exposed again, which offers a structure preferable for coupling of an external wire. Depending on the kind of the resist used for the protective film 30, the removal thereof is difficult in some cases if the base 11 is heated to a temperature higher than 120° C. in the heating process with the heating device 320. Also in terms of this respect, it is desirable that the heating temperature of the base 11 in the heating process is at most 120° C.

Through the above processes, a substrate is obtained that includes a plurality of surface acoustic wave resonators 1, and in which the insulating layer 40 has been formed on certain regions of the surface of the base 11. According to the method of manufacturing a substrate of the present embodiment, the pre-insulating substrate 12 is used that has been provided with the protective film 30 having the peripheral part 31 thicker than the center part 32 thereof. Therefore, a substrate can be manufactured in which insulating treatment has been implemented only for desired regions of the substrate surface and thus the insulating layer 40 has been formed only on the regions. Furthermore, the protective film 30 can be manufactured with high productivity as described above. Accordingly, according to the method of manufacturing a substrate of the present embodiment, the above-described advantages can be achieved without lowering the productivity.

Method of Manufacturing Surface Acoustic Wave Resonator

The substrate thus manufactured is divided into pieces each including one SAW pattern 51, thereby achieving the surface acoustic wave resonator 1 shown in FIGS. 6C and 8E. The surface acoustic wave resonator 1 functions as a resonator that confines surface acoustic wave energy by utilizing reflection of a surface acoustic wave. In the surface acoustic wave resonator 1, since aluminum having conductivity is exposed in the protection regions on the conductive pads 21, external wires can be coupled thereto easily and surely. This structure leads to little possibility of occurrence of troubles due to defects of the coupling to external wires. Furthermore, the surfaces of the IDTs 22 and the reflectors 23 and part of the surfaces of the conductive pads 21 are covered with the insulating layer 40 arising from oxidization of the surface of an aluminum thin film. Therefore, problems are not caused even when a conductive foreign matter or the like adheres to the regions in which the IDTs 22 or the reflectors 23 are disposed. As described above, according to the method of manufacturing a surface acoustic wave resonator including the method of manufacturing a substrate of the present embodiment, the surface acoustic wave resonator 1 having high reliability can be manufactured.

In addition, the method of manufacturing a substrate of the present embodiment can be applied not only to a method of manufacturing a surface acoustic wave resonator serving as a resonator, but also to methods of manufacturing various types of surface acoustic wave resonators typified by surface acoustic wave resonators having a frequency selection function.

Surface Acoustic Wave Device

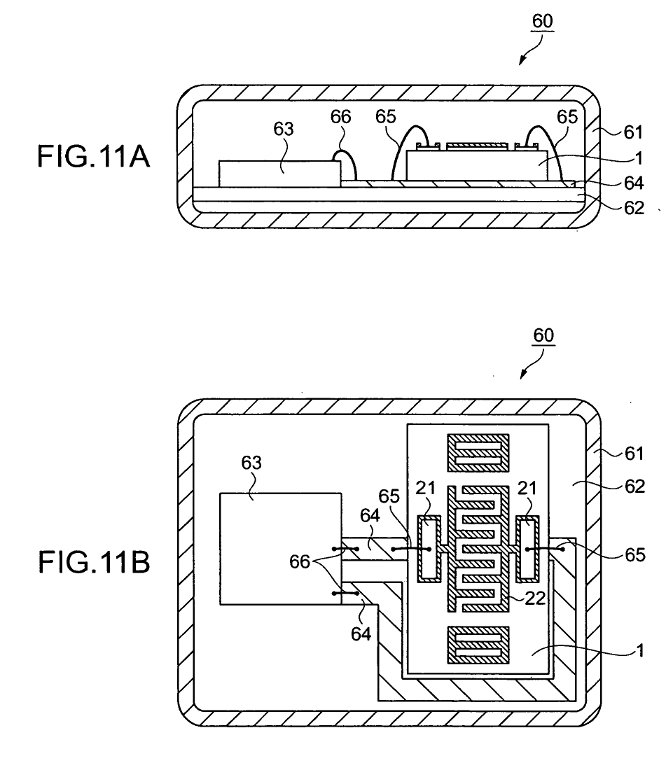

The surface acoustic wave resonator 1 can be incorporated into various devices to thereby use the devices as a surface acoustic wave device. FIGS. 11A and 11B are schematic diagrams of an oscillator 60 as a surface acoustic wave device incorporating the surface acoustic wave resonator 1. FIG. 11A is a side sectional view of the oscillator 60. FIG. 11B is a plan view of the oscillator 60. The oscillator 60 includes a package 61, a base portion 62, an integrated circuit 63, interconnections 64, metal wires 65 and 66, and the surface acoustic wave resonator 1. On the upper surface of the base portion 62, the surface acoustic wave resonator 1 and the integrated circuit 63 for driving the surface acoustic wave resonator 1 are mounted, and the interconnections 64 for electrically coupling the surface acoustic wave resonator 1 to the integrated circuit 63 are patterned. The surface acoustic wave resonator 1 is electrically coupled to the interconnection 64 by the metal wires 65. The integrated circuit 63 is electrically coupled to the interconnection 64 by the metal wires 66. The metal wires 65 and 66 are composed of a gold wire or the like. The metal wires 65 are coupled to the surface acoustic wave resonator 1 by wire bonding through the aluminum-exposed region on the conductive pads 21, i.e., the protection regions. The package 61 covers the base portion 62 and parts disposed on the base portion 62 to seal them.

In the oscillator 60 of the present embodiment, aluminum having conductivity is exposed in the protection regions on the conductive pads 21 of the surface acoustic wave resonator 1. Thus, the metal wires 65 can be coupled to the surface acoustic wave resonator 1 easily and surely. This structure leads to little possibility of occurrence of troubles due to defects of the coupling to the metal wires. Furthermore, since the IDTs 22 and the reflectors 23 on the surface acoustic wave resonator 1 are covered with the insulating layer 40, problems do not arise even if a conductive foreign matter enters the package 61 and adheres to the IDTs 22 or the reflectors 23. As described above, applying the surface acoustic wave resonator of the present embodiment to a surface acoustic wave device can achieve high reliability.

Moreover, the surface acoustic wave resonator of the present embodiment can be applied to, besides the oscillator 60, various surface acoustic wave devices typified by frequency filters.

Electronic Apparatus

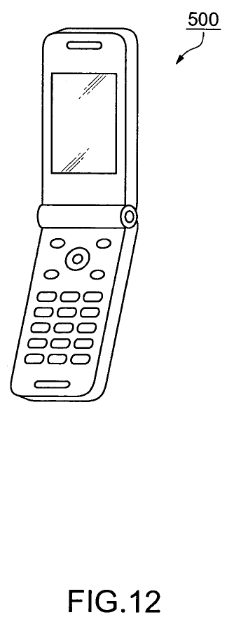

Description will be made about an example of application of the above-described surface acoustic wave device to an electronic apparatus. FIG. 12 is a schematic diagram of a cellular phone 500 including therein the oscillator 60 as a surface acoustic wave device. The cellular phone 500 has the oscillator 60 with high reliability, and therefore keeps its favorable operation over a long period. The surface acoustic wave device of the present embodiment can be applied to, besides the cellular phone 500, various electronic apparatuses typified by personal computers, portable electronic terminals and watches.

It should be noted that the embodiments of the invention described above can be modified variously without departing from the scope and spirit of the invention. For example, the following modifications are available.

First Modification

The above-described embodiment includes a step of heating the base 11 with the heating device 320 in order to form the protective film 30 having the peripheral part 31 thicker than the center part 32, and a step of applying the protective material 30A with using the droplet discharge device 330. Alternatively, instead of these steps, the embodiment may include a step of applying, with using the droplet discharge device 330, the protective material 30A containing the solvent with a boiling point in the range of 170° C. to 250° C. This modification is based on the fact that the ratio a/b can be increased not only by increasing the temperature of the base 11 but also by using the protective material 30A of which solvent has a high boiling point. Experiments by the inventors have confirmed that, if the boiling point of the solvent in the protective material 30A is in the range of 170° C. to 250° C., the protective film 30 that has the peripheral part 31 thicker than the center part 32 and thus has sufficient robustness against the anodization can be formed even through no heating of the base 11.

In the method of manufacturing a substrate according to the present modification, the base 11 cleaned in the cleaning device 310 is carried to the droplet discharge device 330 without passing through the heating process with the heating device 320, followed by being provided with the protective material 30A of which the solvent has a boiling point from 170° C. to 250° C. The present modification is basically the same as the above-described embodiment except for this respect. The present modification can omit the heating process of the base 11, and thus can shorten the tact time for the substrate manufacturing process.

Note that the present modification does not mean that the heating process by the heating device 320 must be omitted if the protective material 30A of which solvent has a boiling point from 170° C. to 250° C. is used. If the protective material 30A of which solvent has a boiling point from 170° C. to 250° C. is applied after the base 11 is heated by the heating device 320, the protective film 30 having the peripheral part 31 thicker than the center part 32 can be formed more easily.

Second Modification

In the above-described embodiment, anodization is used as treatment for providing the surface of an aluminum thin film with insulation. However, any method may be used for the insulating treatment as long as the method allows formation of an insulating layer on the surface of the base 11. For example, besides the anodization, thermal oxidization may be used in which the base 11 is heated after being loaded in a chamber including a gas such as an oxygen gas, to thereby form an oxide film on the surface of the base 11. Also by the method of manufacturing a substrate including such insulating treatment, a substrate can be manufactured in which the insulating layer 40 has been formed only on desired regions of the substrate surface.

Third Modification

In the above-described embodiment, the base 11 is heated in a thermostatic chamber as the heating device 320. Besides this method, any method for heating the base 11 is available as long as the method ensures that the base 11 has been heated to a certain temperature at the time of applying the protective material 30A on the base 11. For example, a method may be used in which a base heating unit is provided for the stage 106 of the droplet discharge device 330 and the base heating unit heats the base 11 carried to the stage 106. Alternatively, a method may also be used in which the droplet discharge device 330 is provided with a heat radiation unit such as a lamp that can heat the stage 106, and the base 11 carried to the stage 106 is heated by the heat radiation unit. Also according to the method of manufacturing a substrate including such a heating process, with using the protective film 30 having the peripheral part 31 thicker than the center part 32, a substrate can be manufactured in which the insulating layer 40 has been formed only on desired regions of the substrate surface.

Fourth Modification

In the above-described embodiment, a substrate is manufactured from the base 11 composed of the quartz wafer 50 having thereon an aluminum thin film. Besides the base 11, any base may be used to manufacture a substrate as long as the base has conductive portions on the surface thereof. For example, a silicon wafer or the like having metal wires on the surface thereof may be used as a base. Also when using such a base, a substrate can be manufactured in which the insulating layer 40 has been formed only on desired regions of the substrate surface.

What is claimed is:

1. A pre-insulating substrate, comprising:
a base including an electrically conductive portion on a surface of the base; and
a protective film disposed on the surface of the base to cover part of the conductive portion so as to prevent insulating treatment from being implemented for the part of the conductive portion, the protective film having a peripheral part that is thicker than a region other than the peripheral part in the protective film.

2. The pre-insulating substrate according to claim 1, wherein a thickness of the peripheral part is at least twice a thickness of the region other than the peripheral part and is at most ten times the thickness of the region.

3. The pre-insulating substrate according to claim 1, wherein a material of the protective film is resist.

4. A method of manufacturing a substrate by implementing insulating treatment for a region other than part of an electrically conductive portion on a surface of a base, the method comprising:
heating the base that includes the conductive part on the surface of the base;
applying a functional liquid on the base by using a droplet discharge device so as to cover the part of the conductive portion;
drying the functional liquid to form a pre-insulating substrate including a protective film on a surface of the pre-insulating substrate, the protective film having a peripheral part that is thicker than a region other than the peripheral part in the protective film;
implementing insulating treatment for the surface of the pre-insulating substrate; and
removing the protective film.

5. A method of manufacturing a substrate by implementing insulating treatment for a region other than part of an electrically conductive portion on a surface of a base, the method comprising:
applying a functional liquid on the base that includes the conductive portion on the surface of the base by using a droplet discharge device so as to cover the part of the conductive portion, a solvent of the functional liquid having a boiling point in a range from 170° C. to 250° C.;
drying the functional liquid to form a pre-insulating substrate including a protective film on a surface of the pre-insulating substrate, the protective film having a peripheral part that is thicker than a region other than the peripheral part in the protective film;
implementing insulating treatment for the surface of the pre-insulating substrate; and
removing the protective film.

6. The method of manufacturing a substrate according to claim 5, further comprising prior to the applying a functional liquid:
heating the base.

7. The method of manufacturing a substrate according to claim 4, wherein the insulating treatment includes treatment with anodization.

8. The method of manufacturing a substrate according to claim 4, wherein a thickness of the peripheral part of the protective film is at least twice a thickness of the region other than the peripheral part and is at most ten times the thickness of the region.

9. The method of manufacturing a substrate according to claim 4, wherein in the heating the base, the base is heated to a temperature in a range from 30° C. to 120° C.

10. The method of manufacturing a substrate according to claim 4, wherein in the heating the base, the base is heated to a temperature in a range from 40° C. to 60° C.

11. The method of manufacturing a substrate according to claim 4, wherein the functional liquid includes resist.

12. A method of manufacturing a surface acoustic wave resonator including the method of manufacturing a substrate according to claim 4.

13. A surface acoustic wave resonator manufactured by using the method according to claim 12.

14. A surface acoustic wave device including the surface acoustic wave resonator according to claim 13.

15. An electronic apparatus including the surface acoustic wave device according to claim 14.
